(19) United States
(12) Patent Application Publication
(10) Pub. No.: US 2026/0339316 A1
(43) Pub. Date: Oct. 29, 2026

(54) SYSTEM AND METHOD FOR TRACKING AND MANAGING THERMAL PASTE DEGRADATION IN PROCESSING UNITS

(71) Applicant: Aivres Systems Inc., San Jose, CA (US)

(72) Inventor: Shin-Chi SHEN, Taipei City (TW)

(21) Appl. No.: 19/187,318

(22) Filed: Apr. 23, 2025

(51) Int. Cl. G05B 23/02; H05K 7/20

(52) U.S. Cl. CPC G05B 23/0283; G05B 23/0243; H05K 7/20209; H05K 7/20454

(57) ABSTRACT

A system for managing the lifespan of thermal paste applied to a processing unit (PU) includes a baseboard management controller (BMC) communicatively coupled to the PU and a temperature sensor configured to transmit temperature data to the BMC. The system stores a baseline lifespan value corresponding to a reference temperature for the thermal paste and receives temperature data over multiple time intervals. The system determines a lifespan deduction factor for each interval based on the received temperature data and calculates an estimated remaining lifespan of the thermal paste by adjusting the baseline lifespan value according to the deduction factors. When the remaining lifespan falls below a configurable threshold, the system generates an alert indicating thermal paste degradation risk. The system enables proactive thermal paste maintenance to prevent overheating and ensure stable PU performance.

### TECHNICAL FIELD

The present disclosure relates generally to the field of thermal management in electronic systems, and more particularly to methods and systems for tracking and managing the lifespan and effectiveness of thermal paste used in central processing units (CPUs), graphic processing units (GPUs), neural network processing units (NPUs), and similar electronic components.

### BACKGROUND

In modern computing systems, efficient thermal management is critical for ensuring optimal performance and longevity of CPUs, GPUs, NPUs, or other types of processing units (collectively called “PU” in this disclosure). A typical processing unit cooling system comprises a heat sink coupled to the PU via a thermally conductive material, commonly referred to as thermal paste or thermal compound. The thermal paste fills microscopic surface imperfections between the PU and heat sink to improve heat transfer and prevent air gaps that can reduce cooling efficiency.

Most commercially available thermal pastes are composed of a blend of thermally conductive materials, such as metal oxides or carbon-based compounds, suspended in an oil-based medium. While the thermal paste initially provides an effective heat transfer pathway, its performance can degrade over time due to thermal cycling and sustained exposure to elevated temperatures. This degradation process, characterized by the evaporation or drying of the oil content, leads to a solidification of the compound and a decline in its thermal conductivity. As a result, the PU may experience increased operating temperatures, which can contribute to thermal throttling or even system failure if left unaddressed.

Despite the critical role of thermal paste, existing thermal management solutions primarily focus on real-time temperature monitoring without accounting for the time-based deterioration of the thermal paste. Consequently, there is a need for systems and methods that can proactively monitor the thermal paste's condition, predict its remaining lifespan based on PU temperature data, and provide timely maintenance alerts to prevent overheating-related failures.

### SUMMARY

A system of one or more computers can be configured to perform particular operations or actions by virtue of having software, firmware, hardware, or a combination thereof installed on the system that, in operation, causes the system to perform the actions. One or more computer programs can be configured to perform particular operations or actions by including instructions that, when executed by a data processing apparatus, cause the apparatus to perform the actions.

In one general aspect, the system may include a baseboard management controller (BMC). The system may also include a temperature sensor configured to measure the temperature data of the processing unit (PU) over time and transmit the temperature data to the BMC. The system may furthermore include a non-transitory, machine-readable storage medium storing instructions that, when executed by the BMC, cause the system to store a baseline lifespan value corresponding to a reference temperature for the thermal paste, receive temperature data of the PU during operation over a plurality of time intervals, and determine, for each time interval, a lifespan deduction factor based on the received temperature data. The lifespan deduction factor may include a reduction in the baseline lifespan value. The system may determine an estimated remaining lifespan of the thermal paste based on the lifespan deduction factor and the baseline lifespan value. When the estimated remaining lifespan of the thermal paste falls below a predefined threshold, the system generates an alert indicating a degradation risk of the thermal paste. Other embodiments of this aspect may include corresponding computer systems, apparatuses, and computer programs recorded on one or more computer storage devices, each configured to perform the actions of the methods.

Implementations may include one or more of the following features. In some implementations, the system may process the temperature data using at least one model selected from a group consisting of polynomial interpolation, curve fitting, weighted averaging, or regression-based modeling to determine the lifespan deduction factor that correlates the temperature data of the PU to a time-based degradation rate of the thermal paste. To determine the estimated remaining lifespan of the thermal paste based on the lifespan deduction factor and the baseline lifespan value, the system may feed a series of lifespan deduction factors to a predictive machine learning model to extrapolate future PU temperature trends and forecast the estimated remaining lifespan of the thermal paste based on the series of lifespan deduction factors and anticipated operational conditions.

The predictive machine learning model may include a recurrent neural network (RNN) model, a long short-term memory (LSTM) network, or a gated recurrent unit (GRU) network trained on historical temperature data and corresponding lifespan deduction factors. The machine learning model may be trained using at least one supervised learning algorithm. In such implementations, the system may pre-process historical operational data and temperature logs to normalize and label data points corresponding to different levels of thermal paste degradation. The system may train the predictive machine learning model on the labeled data using a gradient-based optimization technique, allowing the model to learn correlations between CPU temperatures, usage patterns, and known time-to-failure intervals for the thermal paste. Once trained, the system may deploy the predictive machine learning model to infer the estimated remaining lifespan of the thermal paste in real time based on continuously updated PU temperature data and operational conditions.

The system may also be configured to initiate at least one remedial action through a hardware control interface. The remedial action may include adjusting the CPU cooling fan speed, triggering a maintenance routine through firmware, or activating a visual indicator, such as an LED light, to signal a need for reapplication or replacement of the thermal paste. The predefined threshold for generating an alert may be adjustable via firmware updates or software interfaces, allowing customization of the alert generation to notify users a specified number of days before the estimated end of the lifespan of the thermal paste.

The temperature sensor may be configured to measure the PU temperature data at a sampling rate of approximately 1000 Hz and with a precision of ±1 °C. The system may collect temperature data points totaling at least an order of one thousand data points over a 24-hour period. The baseline lifespan value may be predefined based on a pre-selected reference temperature, and the lifespan deduction factor may include a temperature-dependent scaling value. In one example, the temperature-dependent scaling value may include a deduction of five days from the baseline lifespan for each day the PU operates at approximately 60 °C, four days for operation at 50 °C, and one day for operation at 30 °C.

Implementations of the described techniques may include hardware, a method or process, or a computer-readable medium.

In one general aspect, the method may include storing, in a baseboard management controller (BMC), a baseline lifespan value corresponding to a reference temperature for the thermal paste. The method may also include receiving, by the BMC, temperature data of the PU during normal operation over a plurality of time intervals. The method may furthermore include determining, for each time interval, a lifespan deduction factor based on the received temperature data, where the lifespan deduction factor may include a reduction in the baseline lifespan value. The method may also include determining an estimated remaining lifespan of the thermal paste by deducting cumulative lifespan reductions from the baseline lifespan value. The method may additionally include generating an alert when the estimated remaining lifespan of the thermal paste falls below a predefined threshold, indicating that the thermal paste requires maintenance or replacement. Other embodiments of this aspect may include corresponding computer systems, apparatuses, and computer programs recorded on one or more computer storage devices, each configured to perform the actions of the methods.

In one general aspect, a non-transitory computer-readable storage medium may store instructions for performing the operations described. The storage medium may include instructions for storing a baseline lifespan value corresponding to a reference temperature for the thermal paste in a BMC, receiving temperature data of the PU during normal operation over a plurality of time intervals, and determining a lifespan deduction factor based on the received temperature data. The instructions may also include determining an estimated remaining lifespan of the thermal paste by deducting cumulative lifespan reductions from the baseline lifespan value and generating an alert when the estimated remaining lifespan falls below a predefined threshold, indicating that the thermal paste requires maintenance or replacement. Other embodiments of this aspect may include corresponding computer systems, apparatuses, and computer programs recorded on one or more computer storage devices, each configured to perform the actions of the methods.

### BRIEF DESCRIPTION OF THE DRAWINGS

Certain features of various embodiments of the present technology are set forth with particularity in the appended claims. A better understanding of the features and advantages of the technology will be obtained by reference to the following detailed description that sets forth illustrative embodiments, in which the principles of the disclosure are utilized, and the accompanying drawings of which:

FIG. 1 shows an example usage of thermal paste for keeping a processing unit (e.g., a CPU) cool and running properly, according to one example embodiment.

FIG. 2 is an example lifespans of thermal paste from different manufacturers, according to one example embodiment.

FIG. 3 is an example process for real-time monitoring, predicting, and reporting of thermal paste lifespan degradation, according to one example embodiment.

FIG. 4 is an example mapping table between temperature measurements and lifespan deduction of thermal paste, according to one example embodiment.

FIG. 5 is an example process of replacing or reapplying thermal paste triggered by the alert, according to one example embodiment.

FIG. 6 illustrates an example method for real-time monitoring, predicting, and reporting of thermal paste lifespan degradation, according to one example embodiment.

FIG. 7 illustrates a block diagram of an example computer system in which various of the embodiments described herein may be implemented.

### DETAILED DESCRIPTION OF EMBODIMENTS

In the following description, certain specific details are set forth in order to provide a thorough understanding of various embodiments of the disclosure. However, one skilled in the art will understand that the disclosure may be practiced without these details. Moreover, while various embodiments of the disclosure are disclosed herein, many adaptations and modifications may be made within the scope of the disclosure in accordance with the common general knowledge of those skilled in this art. Such modifications include the substitution of known equivalents for any aspect of the disclosure in order to achieve the same result in substantially the same way.

Unless the context requires otherwise, throughout the present specification and claims, the word “comprise” and variations thereof, such as, “comprises” and “comprising” are to be construed in an open, inclusive sense, that is as “including, but not limited to.” Recitation of numeric ranges of values throughout the specification is intended to serve as a shorthand notation of referring individually to each separate value falling within the range inclusive of the values defining the range, and each separate value is incorporated in the specification as it were individually recited herein. Additionally, the singular forms “a,” “an” and “the” include plural referents unless the context clearly dictates otherwise.

Reference throughout this specification to “one embodiment” or “an embodiment” means that a particular feature, structure or characteristic described in connection with the embodiment is included in at least one embodiment of the present disclosure. Thus, the appearances of the phrases “in one embodiment” or “in an embodiment” in various places throughout this specification are not necessarily all referring to the same embodiment, but may be in some instances. Furthermore, the particular features, structures, or characteristics may be combined in any suitable manner in one or more embodiments.

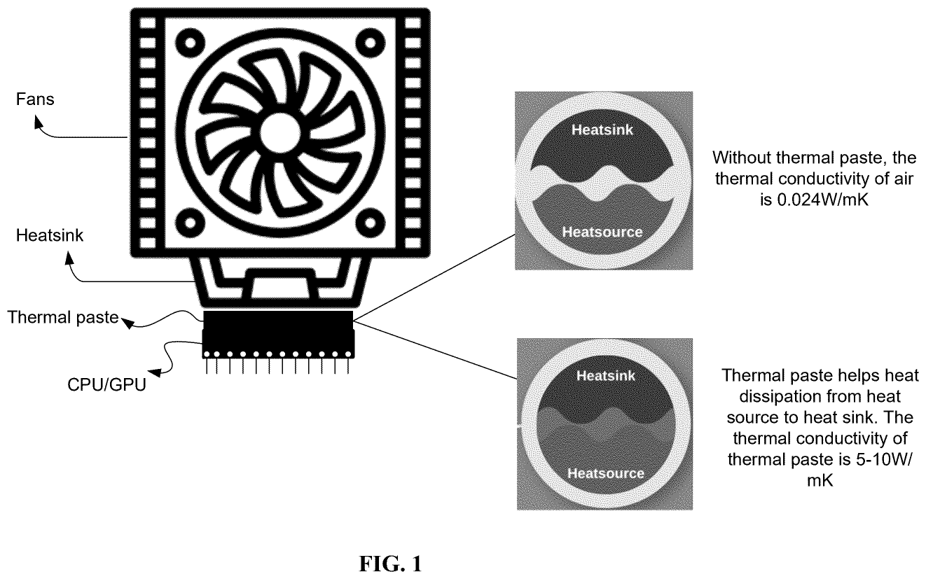

FIG. 1 shows an example usage of thermal paste for keeping a processing unit (PU) (e.g., a CPU, GPU, NPU, or another type of heat-generating processing unit) cool and running properly, according to one example embodiment.

In the example configuration illustrated in FIG. 1, the PU is positioned at the bottom of the stack. Resting on top of its surface is a thin layer of thermal paste, which serves to bridge microscopic gaps and ensure efficient heat transfer between the processing unit and the heat sink. The heat sink itself sits firmly on this thermal paste layer to absorb and diffuse the heat, and a fan is coupled to the heat sink to facilitate active cooling.

Without thermal paste, air would fill the small voids between the processing unit and the heat sink, resulting in a significantly lower heat transfer rate. Specifically, air's thermal conductivity is around 0.024 W/mK (Watts per meter-Kelvin), which impedes effective heat flow. By comparison, thermal paste typically provides a thermal conductivity of about 5 to 10 W/mK, making it far superior in transferring heat away from the processing unit.

This distinction is critical in modern high-performance computing environments, where substantial heat is generated by advanced workloads and sophisticated operations, especially in AI-related tasks that push the limits of processing capacity. Effective heat dissipation not only preserves the reliability of these processing units but also enables them to maintain peak performance without risking thermal shutdown or damage, an essential requirement in today's demanding data centers and AI-focused hardware deployments.

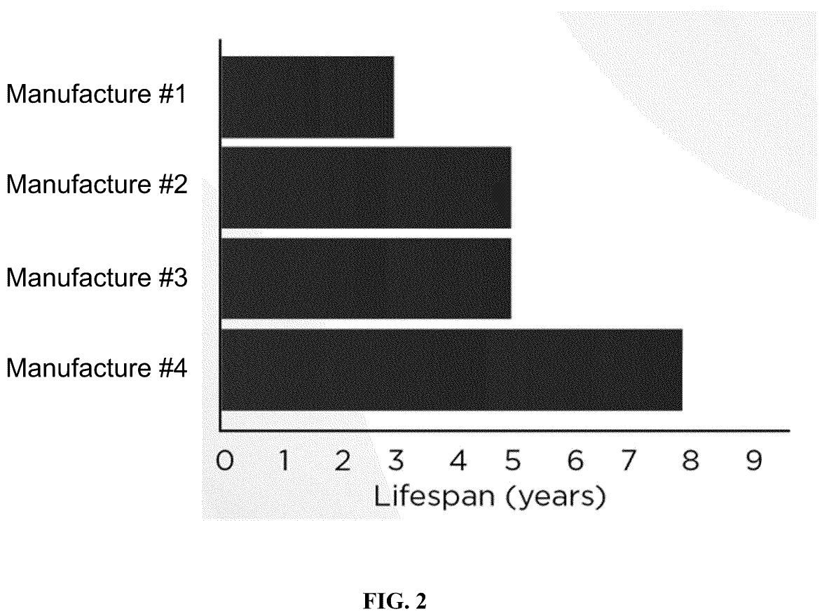

FIG. 2 is an example lifespans of thermal paste from different manufacturers, according to one example embodiment. Lifespans of thermal paste from different manufacturers may vary due to several factors, such as the specific chemical composition and formulation of each paste. Some manufacturers use higher-grade oils or synthetic compounds that are more resistant to evaporation or drying, which can extend the effective life of the thermal paste before it begins to lose conductivity. Others may incorporate special additives or binders that enhance thermal performance under sustained high temperatures, while still others might focus on affordability and ease of application, leading to a shorter lifespan.

In real-world use, a type of thermal paste can exhibit noticeably different lifespans depending on the temperatures under which its associated heat-generating component is operated. When the component functions within lower temperature ranges, the thermal paste retains its properties for a comparatively longer duration. In contrast, continuous operation at higher temperatures—whether due to intensive workloads, overclocking, or warmer ambient conditions—accelerates chemical breakdown, leading to faster deterioration of the paste's thermal conductivity. As a result, the same thermal paste may require replacement sooner if it is consistently exposed to more demanding thermal environments.

Therefore, accurately predicting the rate at which thermal paste degrades requires both a reference point and a method of correlating temperature exposure to the corresponding lifespan reduction. First, the system relies on a baseline lifespan value, typically measured at a relatively low and stable temperature, such as 30 °C, to represent the thermal paste's maximum operating duration under minimal stress. From this reference, the system may use either a mapping table or a machine learning model to learn how quickly the paste deteriorates under varying temperature ranges. The mapping table can be based on empirical data showing how many “virtual days” of paste life are effectively consumed during continuous operation at a given elevated temperature. Alternatively, a trained machine learning model can learn these relationships from historical usage patterns and temperature logs, allowing it to dynamically calculate the life deduction factor for any given time interval.

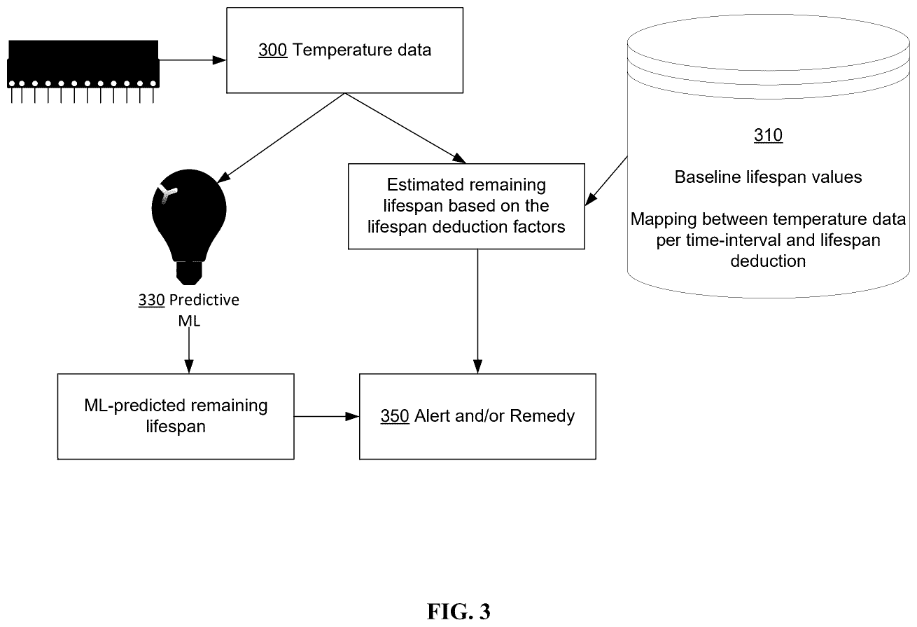

FIG. 3 is an example process for real-time monitoring, predicting, and reporting of thermal paste lifespan degradation, according to one example embodiment.

As shown, temperature data 300 of the PU are continuously or periodically measured and collected by a sensor positioned to reflect the PU's operational heat.

In some embodiments, a database 310 may be configured to store two principal categories of information. First, the database 310 may store a baseline lifespan value measured under a specific reference temperature, for example 30 °C, representing the upper limit of the thermal paste's operational life in minimal-stress conditions. Second, the database 310 may store a mapping that correlates time-interval temperature data to lifespan deduction factors. These factors indicate how much of the baseline lifespan is effectively consumed when the PU operates within certain temperature ranges for given lengths of time. In some embodiments, the database may be part of a baseboard management controller (BMC).

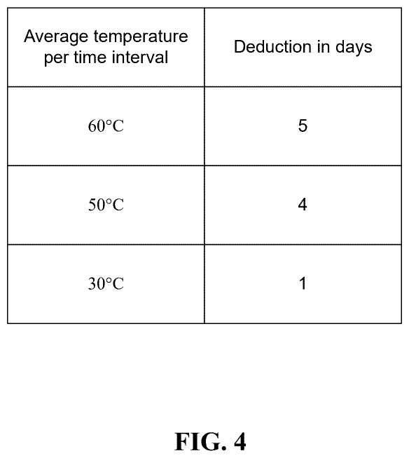

FIG. 4 illustrates an example mapping table between temperature measurements and lifespan deduction of thermal paste, according to one example embodiment. In this example, each entry associates a specific temperature range or average temperature with a certain number of “virtual days” to deduct from the baseline lifespan. The underlying rationale is that higher operational temperatures accelerate the chemical or structural breakdown of the thermal paste, thus consuming its usable lifespan more rapidly.

By way of example, if the temperature of the processing unit (PU) remains around 60 °C for one full day, the system deducts five days from the thermal paste's baseline lifespan (and the remaining lifespan becomes the new baseline lifespan). This reflects a relatively high stress condition compared to cooler operating temperatures. If the PU runs at approximately 50 °C for a day, four days are subtracted, illustrating a slightly slower rate of paste degradation. Operating at around 30 °C for the same duration deducts only one day, corresponding to normal wear under minimal thermal stress. By referencing this mapping table in real time, the system can continuously update the estimated remaining lifespan of the thermal paste and generate alerts or initiate remedial actions when the threshold for replacement is approached.

Referring back to FIG. 3, the process illustrates two different approaches for estimating the remaining lifespan of the thermal paste. In one approach, the system calculates the remaining lifespan of the thermal paste by comparing the observed temperature for each time interval (e.g., every 6 hours, 12 hours, 24 hours, etc.) against the stored mapping table. The corresponding lifespan deduction factor is subtracted from the baseline lifespan value, and the result is an updated remaining lifespan. This deduction-based method allows real-time monitoring and gradual depletion of the baseline value as the PU undergoes normal or intensive workloads.

In another approach, the system employs a predictive machine learning model 330. This model receives real-time temperature data collected over multiple time intervals, capturing not just a single snapshot but an evolving pattern of temperature changes. Using these historical temperature patterns, the model forecasts potential future temperature trajectories. Drawing upon the mapping between temperature data and expected degradation rates, the model produces a predicted remaining lifespan of the thermal paste without requiring an exclusively manual deduction for each interval.

Both approaches converge on the task of determining whether the thermal paste is nearing the end of its functional life. If the estimated remaining lifespan, whether generated by the mapping approach or the predictive machine learning model, falls below a predefined threshold, the system triggers an alert indicating that the thermal paste is at heightened risk of failure. In some embodiments, the system may also initiate at least one remedial action through a hardware control interface, such as adjusting fan speed to mitigate heat buildup, prompting a firmware-based maintenance routine, or activating a visual indicator—such as an LED light—to signal that reapplication or replacement of the thermal paste is advisable.

As a specific example, the system illustrated in FIG. 3 may include a BMC that interfaces directly with a temperature sensor that measures the PU's thermal output at a high sampling rate, such as approximately 1000 Hz, ensuring that time-sensitive temperature data is continuously available. The sensor's precision can be ±1 °C, and over a 24-hour period, at least an order of one thousand data points may be gathered.

Upon receiving the temperature data, the BMC may retrieve both a baseline lifespan value and a set of instructions for determining how temperature exposure relates to thermal paste degradation. This baseline lifespan value corresponds to a reference temperature—for instance, a room temperature such as 30 °C—which establishes the starting point of how long the thermal paste is expected to remain effective under minimal stress. As the PU operates across multiple time intervals, the system identifies the temperature ranges for those intervals and calculates a lifespan deduction factor. A temperature-dependent scaling value may be used here, effectively reducing the baseline lifespan in proportion to the severity and duration of temperature exposure. For example, consistently running the PU at higher temperatures will more rapidly consume the thermal paste's effective life compared to running it under cooler conditions.

In addition to the direct deduction approach, the system may feed a series of these lifespan deduction factors to a predictive machine learning model. This model can be based on advanced algorithms, such as polynomial interpolation, regression-based techniques, or more intricate neural architectures like recurrent neural networks (RNN), long short-term memory (LSTM) networks, or gated recurrent units (GRU). Before training, the system normalizes and labels historical operational data—which may include temperature logs and known intervals leading to thermal paste failure—to map each degradation stage accurately. A supervised learning method, e.g., employing gradient-based optimization, is then used to train the model, enabling it to learn correlations between PU temperatures, usage patterns, and observed time-to-failure. Once trained, the model predicts future temperature trajectories and estimates how quickly the paste will degrade under anticipated operational conditions, providing a forecast of the remaining lifespan that goes beyond simple day-by-day deductions.

Whether using a direct deduction method or the predictive model, if the resulting estimate of remaining thermal paste lifespan falls below a configurable threshold, the system triggers an alert indicating imminent risk of paste failure. This threshold may be adjustable through firmware updates or software interfaces, permitting operators to receive warnings a specific number of days before the paste would nominally expire. In response to such an alert, one or more remedial actions can be taken automatically.

When the estimated remaining lifespan of the thermal paste falls below a set threshold, the BMC may, for instance, initiate a hardware control interface to adjust a cooling fan's speed, launch a firmware-driven maintenance routine, or activate a visual indicator—such as an LED light—signaling that a reapplication or replacement of the thermal paste is advised. In one example, the BMC sends a command to the fan controller to increase the fan speed, for instance by adjusting the duty cycle from a normal level (such as 40% at 1800 rpm) to a higher level (such as 80% at 3600 rpm). The increased airflow helps lower the temperature of the processing unit and slows further degradation of the thermal paste. In some embodiments, the fan speed adjustment is performed in a multi-stage or continuous manner based on the proximity to the predicted paste failure threshold. For example, if the remaining lifespan is estimated to be less than 20% of the baseline, the fan is operated at a moderate speed (e.g., 60% duty cycle); if the remaining lifespan drops below 10%, the duty cycle is further increased (e.g., to 80% or higher). This dynamic scaling helps slow the degradation rate of the paste and avoid abrupt changes in system behavior.

Alternatively or additionally, the BMC may apply a firmware-level setting that reduces the clock speed and voltage of the processing unit, placing the system into a lower power mode that reduces heat output. In some embodiments, this performance throttling is also tiered. For example, when the remaining thermal paste lifespan is between 20% and 10%, the processor frequency may be reduced by 10-15%, while below 10%, the frequency and voltage may be reduced by 25% or more, thereby substantially lowering the heat output to extend the remaining paste life.

Alternatively or additionally, the BMC may start a maintenance routine stored in firmware. The routine may write an entry in the system event log, send a notification through a management interface, and start a countdown timer. If the timer expires without the issue being addressed, the BMC may shut down the system to prevent possible overheating. The BMC may also turn on a visual indicator, such as switching a front-panel LED from green to blinking amber, to signal to technicians that the thermal paste is near end-of-life. In some embodiments, this visual alert is also adaptive. For example, when the predicted failure point is 7-10 days away, the LED may blink slowly with amber light. If the estimated remaining lifespan drops below 3 days, the blink rate may double and the LED color may change to red. These graduated responses provide a clear signal of urgency and allow technicians to prioritize maintenance scheduling accordingly. The layered actions are based on real-time condition assessments and are directly tied to the specific risk of thermal paste degradation, offering a concrete and technical solution rather than a generic notification.

In some embodiments, the ML-based approach and the direct deduction approach may be executed in parallel, and the results may be compared to assess the reliability of the prediction. If the predicted remaining lifespan values from both approaches are similar, the system assigns a higher confidence score to the prediction. However, if the discrepancy between the predictions exceeds a predefined threshold, the system prioritizes the result of the direct deduction approach as more reliable. Additionally, the system collects the corresponding temperature data and lifespan deduction factors to further fine-tune and retrain the machine learning model, improving its future predictive accuracy.

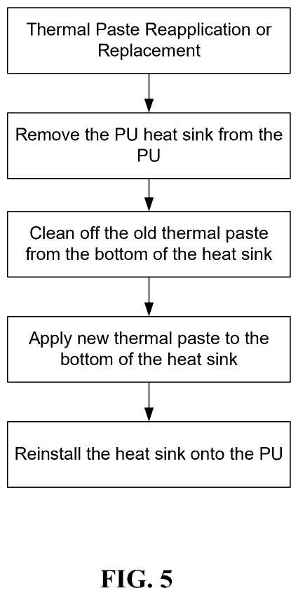

FIG. 5 is an example process of replacing or reapplying thermal paste triggered by the alert, according to one example embodiment.

In some embodiments, the process may begin by powering down the system completely and disconnecting it from any power source to ensure safety during the maintenance procedure. Once powered down, the computer or server case is opened to access the processing unit (PU) and the heat sink assembly. The heat sink is carefully unscrewed and removed from the PU.

After removing the heat sink, the next step involves cleaning off the old thermal paste. Once the surfaces are cleaned and dry, new thermal paste is applied. A small amount, typically “pea-sized” or “rice grain-sized,” is placed at the center of the PU. Care must be taken not to apply too much paste, as excessive amounts can act as an insulator rather than a conductor, hindering efficient heat dissipation. The goal is for the paste to spread evenly across the surface when the heat sink is reinstalled.

Reinstalling the heat sink by aligning it with the PU and gently lowering it into place. The natural pressure from securing the heat sink helps spread the thermal paste uniformly across the PU surface. The screws used to secure the heat sink should be tightened in a diagonal pattern to ensure even pressure distribution, avoiding any air pockets or uneven application of force that could compromise thermal conductivity.

In the case of GPUs, the replacement process may be more involved. The entire cooler assembly may need to be removed, and thermal paste may need to be reapplied not only to the GPU chip itself but also to other components such as VRAM chips, which can also benefit from efficient heat dissipation.

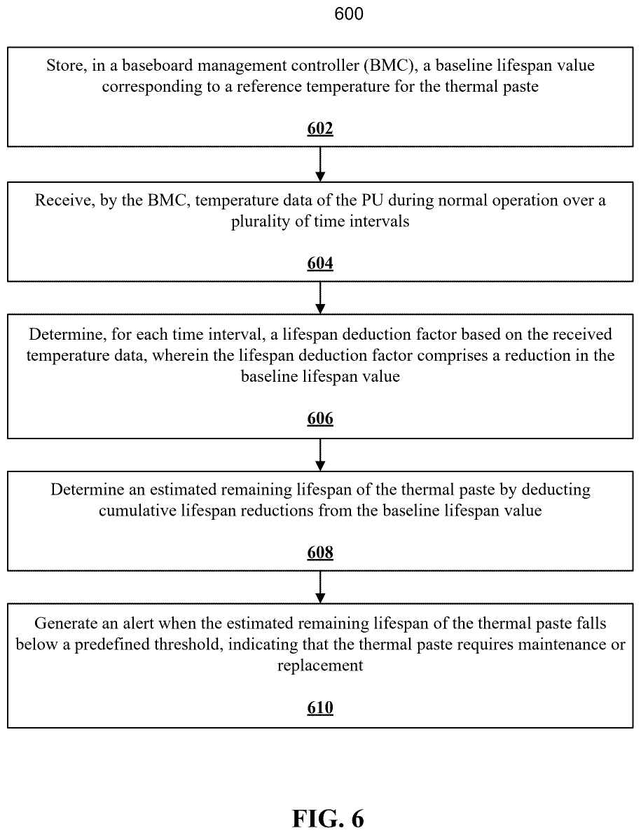

FIG. 6 illustrates an example process 600 for real-time monitoring, predicting, and reporting of thermal paste lifespan degradation, according to one example embodiment. In some implementations, one or more process blocks of FIG. 6 may be performed by a device.

As shown in FIG. 6, process 600 may include storing, in a baseboard management controller (BMC), a baseline lifespan value corresponding to a reference temperature for the thermal paste (block 602). For example, the device may store, in a BMC, a baseline lifespan value corresponding to a reference temperature for the thermal paste, as described above.

As also shown in FIG. 6, process 600 may include receiving, by the BMC, temperature data of the PU during normal operation over a plurality of time intervals (block 604). For example, the device may receive, by the BMC, temperature data of the PU during normal operation over a plurality of time intervals, as described above.

As further shown in FIG. 6, process 600 may include determining, for each time interval, a lifespan deduction factor based on the received temperature data, where the lifespan deduction factor may include a reduction in the baseline lifespan value (block 606). For example, the device may determine, for each time interval, a lifespan deduction factor based on the received temperature data, where the lifespan deduction factor may include a reduction in the baseline lifespan value, as described above.

As also shown in FIG. 6, process 600 may include determining an estimated remaining lifespan of the thermal paste by deducting cumulative lifespan reductions from the baseline lifespan value (block 608). For example, the device may determine an estimated remaining lifespan of the thermal paste by deducting cumulative lifespan reductions from the baseline lifespan value, as described above.

As further shown in FIG. 6, process 600 may include generating an alert when the estimated remaining lifespan of the thermal paste falls below a predefined threshold, indicating that the thermal paste requires maintenance or replacement (block 610). For example, the device may generate an alert when the estimated remaining lifespan of the thermal paste falls below a predefined threshold, indicating that the thermal paste requires maintenance or replacement, as described above.

Process 600 may include additional implementations, such as any single implementation or any combination of implementations described below and/or in connection with one or more other processes described elsewhere herein. In a first implementation, the determining the lifespan deduction factor based on the received temperature data may include: processing the temperature data using at least one model selected from a group having of polynomial interpolation, curve fitting, weighted averaging, or regression-based modeling, to determine the lifespan deduction factor that correlates the temperature data of the PU to a time-based degradation rate of the thermal paste.

A second implementation, alone or in combination with the first implementation, process 600 further includes initiating at least one remedial action through a hardware control interface, where the remedial action may include: adjusting a CPU cooling fan speed, triggering a maintenance routine through firmware, or activating a visual indicator or an LED light to signal a need for reapplication or replacement of the thermal paste.

In a third implementation, alone or in combination with the first and second implementation, the predefined threshold is adjustable via firmware updates or software interfaces, allowing customization of the alert generation to notify a specified number of days before an estimated end of the thermal paste's lifespan.

Although FIG. 6 shows example blocks of process 600, in some implementations, process 600 may include additional blocks, fewer blocks, different blocks, or differently arranged blocks than those depicted in FIG. 6. Additionally, or alternatively, two or more of the blocks of process 600 may be performed in parallel.

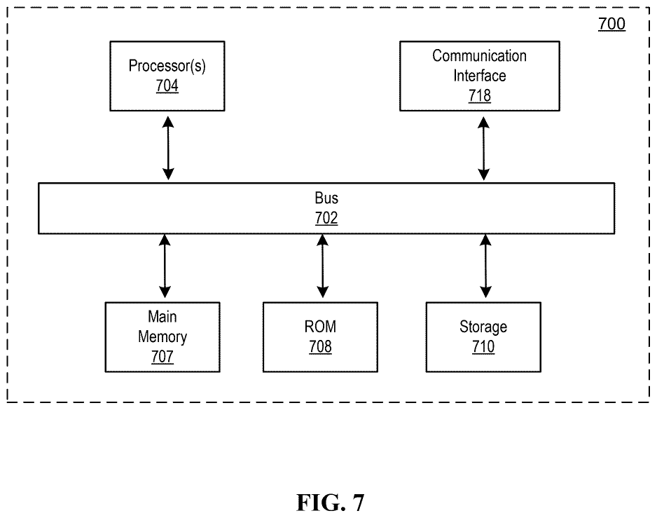

FIG. 7 depicts a block diagram of an example computer system 700 in which various of the embodiments described herein may be implemented. The computer system 700 includes a bus 702 or other communication mechanism for communicating information, one or more hardware processors 704 coupled with bus 702 for processing information. Hardware processor(s) 704 may be, for example, one or more general purpose microprocessors.

The computer system 700 also includes a main memory 707, such as a random-access memory (RAM), cache and/or other dynamic storage devices, coupled to bus 702 for storing information and instructions to be executed by processor 704. Main memory 707 also may be used for storing temporary variables or other intermediate information during execution of instructions to be executed by processor 704. Such instructions, when stored in storage media accessible to processor 704, render computer system 700 into a special-purpose machine that is customized to perform the operations specified in the instructions.

The computer system 700 further includes a read only memory (ROM) 708 or other static storage device coupled to bus 702 for storing computer instructions for processor 704. A storage device 710, such as a magnetic disk, optical disk, or USB thumb drive (Flash drive), etc., is provided and coupled to bus 702 for storing information and instructions.

The computing system 700 may include a user interface module to implement a GUI that may be stored in a mass storage device as executable software codes that are executed by the computing device(s). This and other modules may include, by way of example, components, such as software components, object-oriented software components, class components and task components, processes, functions, attributes, procedures, subroutines, segments of program code, drivers, firmware, microcode, circuitry, data, databases, data structures, tables, arrays, and variables.

The foregoing description of the present disclosure has been provided for the purposes of illustration and description. It is not intended to be exhaustive or to limit the disclosure to the precise forms disclosed. The breadth and scope of the present disclosure should not be limited by any of the above-described exemplary embodiments. Many modifications and variations will be apparent to the practitioner skilled in the art. The modifications and variations include any relevant combination of the disclosed features. The embodiments were chosen and described in order to best explain the principles of the disclosure and its practical application, thereby enabling others skilled in the art to understand the disclosure for various embodiments and with various modifications that are suited to the particular use contemplated. It is intended that the scope of the disclosure be defined by the following claims and their equivalence.

What is claimed is:

1. A system for thermal management of thermal paste applied to a processing unit (PU), comprising:
a baseboard management controller (BMC);
a temperature sensor configured to measure temperature data of the PU over time and transmit the temperature data to the BMC; and
a non-transitory, machine-readable storage medium storing instructions that, when executed by the BMC, cause the system to:
store a baseline lifespan value corresponding to a reference temperature for the thermal paste;
receive temperature data of the PU during operation over a plurality of time intervals;
determine, for each time interval, a lifespan deduction factor based on the received temperature data, wherein the lifespan deduction factor comprises a reduction in the baseline lifespan value;
determine an estimated remaining lifespan of the thermal paste based on the lifespan deduction factor and the baseline lifespan value; and
generate an alert in response to the estimated remaining lifespan of the thermal paste falling below a predefined threshold, indicating a degradation risk of the thermal paste.

2. The system of claim 1, wherein to determine the lifespan deduction factor based on the received temperature data, the system is further configured to:
process the temperature data using at least one model selected from a group consisting of polynomial interpolation, curve fitting, weighted averaging, or regression-based modeling, to determine the lifespan deduction factor that correlates the temperature data of the PU to a time-based degradation rate of the thermal paste.

3. The system of claim 1, wherein to determine the estimated remaining lifespan of the thermal paste based on the lifespan deduction factor and the baseline lifespan value, the system is further configured to:
feed a series of lifespan deduction factors to a predictive machine learning model to extrapolate future PU temperature trends and forecast the estimated remaining lifespan of the thermal paste based on the series of lifespan deduction factors and anticipated operational conditions.

4. The system of claim 3, wherein the predictive machine learning model comprises a recurrent neural network (RNN) model, a long short-term memory (LSTM) network, or a gated recurrent unit (GRU) network trained on historical temperature data and corresponding lifespan deduction factors.

5. The system of claim 3, wherein the predictive machine learning model is trained using a supervised learning algorithm, and the system is further configured to:
pre-process historical operational data and temperature logs to normalize and label data points corresponding to different levels of thermal paste degradation;
train the predictive machine learning model on the labeled data using a gradient-based optimization technique, wherein the predictive machine learning model learns a correlation between CPU temperatures, usage patterns, and known time-to-failure intervals for the thermal paste; and
deploy the trained predictive machine learning model to infer the estimated remaining lifespan of the thermal paste in real time based on continuously updated PU temperature and operational conditions.

6. The system of claim 1, wherein the system is further configured to:
initiate at least one remedial action through a hardware control interface, wherein the remedial action comprises:
adjusting a CPU cooling fan speed,
triggering a maintenance routine through firmware, or
activating a visual indicator or an LED light to signal a need for reapplication or replacement of the thermal paste.

7. The system of claim 1, wherein the predefined threshold is adjustable via firmware updates or software interfaces, allowing customization of the alert generation to notify a specified number of days before an estimated end of the lifespan of the thermal paste.

8. The system of claim 1, wherein the temperature sensor is further configured to:
measure the PU temperature data at a sampling rate of approximately 1000 Hz.

9. The system of claim 1, wherein the temperature sensor is further configured to:
measure the PU temperature data with a precision of ±1 °C to obtain temperature data points.

10. The system of claim 1, wherein the temperature data collected over a 24-hour period total at least an order of one thousand data points.

11. The system of claim 1, wherein the baseline lifespan value is predefined based on a pre-selected temperature.

12. The system of claim 1, wherein the lifespan deduction factor comprises a temperature-dependent scaling value.

13. The system of claim 12, wherein the temperature-dependent scaling value includes:
five days deduction from the baseline lifespan value for each day the PU temperature is approximately 60 °C;
four days deduction from the baseline lifespan value for each day the PU temperature is approximately 50 °C; and
one day deduction from the baseline lifespan value for each day the PU temperature is approximately 30 °C.

14. A method for monitoring and predicting a lifespan of thermal paste applied to a processing unit (PU), comprising:
storing, in a baseboard management controller (BMC), a baseline lifespan value corresponding to a reference temperature for the thermal paste;
receiving, by the BMC, temperature data of the PU during normal operation over a plurality of time intervals;
determining, for each time interval, a lifespan deduction factor based on the received temperature data, wherein the lifespan deduction factor comprises a reduction in the baseline lifespan value;
determining an estimated remaining lifespan of the thermal paste by deducting cumulative lifespan reductions from the baseline lifespan value; and
generating an alert in response to the estimated remaining lifespan of the thermal paste falling below a predefined threshold, indicating that the thermal paste requires maintenance or replacement.

15. The method of claim 14, wherein the determining the lifespan deduction factor based on the received temperature data comprises:
processing the temperature data using at least one model selected from a group consisting of polynomial interpolation, curve fitting, weighted averaging, or regression-based modeling, to determine the lifespan deduction factor that correlates the temperature data of the PU to a time-based degradation rate of the thermal paste.

16. The method of claim 14, further comprising:
initiating at least one remedial action through a hardware control interface, wherein the remedial action comprises:
adjusting a CPU cooling fan speed,
triggering a maintenance routine through firmware, or
activating a visual indicator or an LED light to signal a need for reapplication or replacement of the thermal paste.

17. The method of claim 14, wherein the predefined threshold is adjustable via firmware updates or software interfaces, allowing customization of the alert generation to notify a specified number of days before an estimated end of the thermal paste's lifespan.

18. A non-transitory computer-readable storage medium for monitoring and predicting a lifespan of thermal paste applied to a processing unit (PU), configured with instructions executable by one or more processors to cause the one or more processors to perform operations comprising:
storing, in a baseboard management controller (BMC), a baseline lifespan value corresponding to a reference temperature for the thermal paste;
receiving, by the BMC, temperature data of the PU during normal operation over a plurality of time intervals;
determining, for each time interval, a lifespan deduction factor based on the received temperature data, wherein the lifespan deduction factor comprises a reduction in the baseline lifespan value;
determining an estimated remaining lifespan of the thermal paste by deducting cumulative lifespan reductions from the baseline lifespan value; and
generating an alert in response to the estimated remaining lifespan of the thermal paste falling below a predefined threshold, indicating that the thermal paste requires maintenance or replacement.

19. The non-transitory computer-readable storage medium of claim 18, wherein the operations further comprise:
initiating at least one remedial action through a hardware control interface, wherein the remedial action comprises:
adjusting a CPU cooling fan speed,
triggering a maintenance routine through firmware, or
activating a visual indicator or an LED light to signal a need for reapplication or replacement of the thermal paste.

20. The non-transitory computer-readable storage medium of claim 18, wherein the predefined threshold is adjustable via firmware updates or software interfaces, allowing customization of the alert generation to notify a specified number of days before an estimated end of the thermal paste's lifespan.
